(19) United States
(12) Patent Application Publication
(10) Pub. No.: US 2014/0185346 A1
(43) Pub. Date: Jul. 3, 2014

(54) HYBRID POWER DEVICES AND SWITCHING CIRCUITS FOR HIGH POWER LOAD SOURCING APPLICATIONS

(71) Applicant: EATON CORPORATION, Cleveland, OH (US)

(72) Inventors: Yu Liu, Fox Point, WI (US); Andraw Ho, Taoyuan (TW); Nash Lee, New Taipei (TW); Slobodan Krstic, Brookfield, WI (US)

(73) Assignee: Eaton Corporation, Cleveland, OH (US)

(21) Appl. No.: 13/729,943

(22) Filed: Dec. 28, 2012

(51) Int. Cl. H03K 17/56; H01L 29/739; H02M 7/537; H01L 29/16

(52) U.S. Cl. CPC H03K 17/56; H01L 29/1602; H01L 29/7393; H01L 29/1608; H02M 7/537
USPC 363/131; 257/77; 257/140; 327/419

(57) ABSTRACT

A hybrid switching circuit includes first and second switching devices containing first and second unequal bandgap semiconductor materials. These switching devices, which support parallel conduction in response to first and second control signals, are three or more terminal switching devices of different type. For example, the first switching device may be a three or more terminal wide bandgap switching device selected from a group consisting of JFETs, IGFETs and high electron mobility transistors HEMTs, and the second switching device may be a Si-IGBT. A control circuit is also provided, which is configured to drive the first and second switching devices with first and second periodic control signals having first and second unequal duty cycles. The first duty cycle may be greater than the second duty cycle and the active phases of the second periodic control signal may occur exclusively within the active phases of the first periodic control signal.

### FIELD OF THE INVENTION

The present invention relates to integrated circuit devices and, more particularly, to integrated circuit devices for power switching applications.

### BACKGROUND OF THE INVENTION

Wide bandgap (WBG) power devices such as SiC and GaN power devices can provide superior performance characteristics relative to Si power devices for many high power applications. For example, as disclosed in an article by J. Burm et al., entitled “Wide Band-Gap FETs for High Power Amplifiers,” Journal of Semiconductor Technology and Science, Vol. 6, No. 3, pp. 175-182, September (2006), wide bandgap semiconductor materials having band-gap energy levels in a range from about 2 eV to about 6 eV may be utilized to provide high breakdown voltages for high power generation in power amplifiers and low dielectric constants for better isolation and lower coupling. Similarly, as disclosed in an article by J. Reed et al., entitled “Modeling Power Semiconductor Losses in HEV Powertrains using Si and SiC Devices,” Vehicle Power and Propulsion Conference (VPPC), 2010 IEEE, Sep. 1-3, 2010), silicon carbide (SiC) power devices were shown to have potential benefits over conventional silicon-based devices, particularly in high power electronic converters.

Examples of high power switches that embody wide bandgap semiconductors are disclosed in U.S. Pat. Nos. 7,556,994 and 7,820,511 to Sankin et al., which illustrates normally-off vertical JFET integrated power switches, U.S. Pat. No. 7,230,273 to Kitabatake et al., which describes a plurality of wide bandgap switching elements connected in parallel to increase device yield, and U.S. Pat. No. 8,017,978 to Lidow et al., which illustrates multiple power devices of different type connected in series. Notwithstanding these devices, there continues to be a need for more efficient devices for high power switching applications, including those having lower switching losses and lower cost.

### SUMMARY OF THE INVENTION

High power switching devices according to embodiments of the present invention are utilized to efficiently provide load currents during both light/partial loading conditions and heavy loading conditions. In some of these embodiments of the invention, a hybrid switching circuit is provided, which includes first and second switching devices containing first and second unequal bandgap semiconductor materials, respectively. These first and second switching devices can be electrically coupled as a hybrid switch, which supports parallel conduction in response to first and second control signals received at first and second control terminals of the first and second switching devices, respectively. These first and second switching devices may be three or more terminal switching devices of different type. For example, the first switching device may be a three or more terminal switching device selected from a group consisting of junction field effect transistors (JFETs), insulated-gate field effect transistors (IGFETs) and high electron mobility transistors (HEMTs), and the second switching device may be an insulated-gate bipolar transistor (IGBT). Moreover, the first switching device may include a wide bandgap semiconductor material and the second switching device may utilize silicon. The wide bandgap semiconductor material may be selected from a group consisting of silicon carbide (SiC), gallium nitride (GaN) and diamond.

The hybrid switching circuit may further include a control circuit, which is configured to drive the first and second switching devices with first and second periodic control signals having first and second unequal duty cycles, respectively. The first duty cycle may be greater than the second duty cycle and the active phases of the second periodic control signal may occur exclusively within the active phases of the first periodic control signal. According to preferred aspects of these embodiments of the invention, the active-to-inactive transitions of the second periodic control signal should precede corresponding active-to-inactive transitions of the first periodic control signal. The inactive-to-active transitions of the first periodic control signal can also precede corresponding inactive-to-active transitions of the second periodic control signal, so that turn-on and turn-off switching losses are mostly determined by the first switching device.

Among other applications, these above-described power switching devices may be utilized within many IGBT-based topologies where switching losses are typically very high. For example, in a neutral-point clamped (NPC) inverter (a/k/a “three-level inverter”), a hybrid switch may be used for the “outer” devices because these typically have higher switching losses (i.e., more switching operations per output period) than the “inner” devices. Thus, an NPC inverter according to an embodiment of the invention may include a bus responsive to a DC voltage and a pair of bus capacitors electrically connected in series across the bus. A plurality of parallel inverter “legs” are provided, which are electrically connected across the bus. This plurality of parallel inverter legs includes a first totem pole arrangement of four silicon IGBTs electrically connected in series. First and second wide bandgap transistors are provided, which are electrically connected in parallel with first and fourth IGBTs in the first totem pole arrangement. First and second free-wheeling diodes are provided, which are electrically coupled across second and third IGBTs in the first totem pole arrangement. A first clamp diode is provided, which is electrically connected between a common node in the pair of bus capacitors and a first node in the first totem pole arrangement that is shared by the first and second IGBTs. A second clamp diode is also provided, which is electrically connected between the common node in the pair of bus capacitors and a second node in the first totem pole arrangement that is shared by the third and fourth IGBTs.

A control circuit is also provided, which is configured to drive the first wide bandgap transistor and the first IGBT with first and second periodic control signals having unequal duty cycles when the first totem pole arrangement is driving a first load connected thereto with a first load current. The control circuit is also configured to drive the second wide bandgap transistor and the fourth IGBT with third and fourth periodic control signals having unequal duty cycles. According to preferred aspects of these embodiments of the invention, the first duty cycle is greater than the second duty cycle and the active phases of the second periodic control signal occur exclusively within the active phases of the first periodic control signal. For example, the active-to-inactive transitions of the second periodic control signal may precede corresponding active-to-inactive transitions of the first periodic control signal and the inactive-to-active transitions of the first periodic control signal may precede corresponding inactive-to-active transitions of the second periodic control signal.

### BRIEF DESCRIPTION OF THE DRAWINGS

FIG. 1A is an electrical schematic of a neutral-point clamped (NPC) inverter according to embodiments of the present invention.

FIG. 1B is an electrical schematic of a single inverter “leg” taken from the NPC inverter of FIG. 1A.

FIG. 1C is a graph of an output voltage that can be generated by the inverter leg illustrated by FIG. 1B.

FIG. 1D is a graph of a phase-to-phase output voltage that can be generated by the NPC inverter of FIG. 1A.

FIG. 2A is an electrical schematic of a hybrid power switch according to an embodiment of the present invention.

FIG. 2B is a block diagram of a control circuit according to an embodiment of the present invention, which may be used to provide control signals to the hybrid power switch of FIG. 2A.

FIG. 3A is a timing diagram that illustrates timing of signals generated by the control circuit of FIG. 2B during light/partial load conditions.

FIG. 3B is a timing diagram that illustrates timing of signals generated by the control circuit of FIG. 2B during heavy load conditions.

FIG. 4 is an electrical schematic of a boost converter according to embodiments of the present invention.

### DETAILED DESCRIPTION OF EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

It will be understood that when an element or layer is referred to as being “on,” “connected to” or “coupled to” another element or layer (and variants thereof), it can be directly on, connected or coupled to the other element or layer or intervening elements or layers may be present. In contrast, when an element is referred to as being “directly on,” “directly connected to” or “directly coupled to” another element or layer (and variants thereof), there are no intervening elements or layers present. Like reference numerals refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

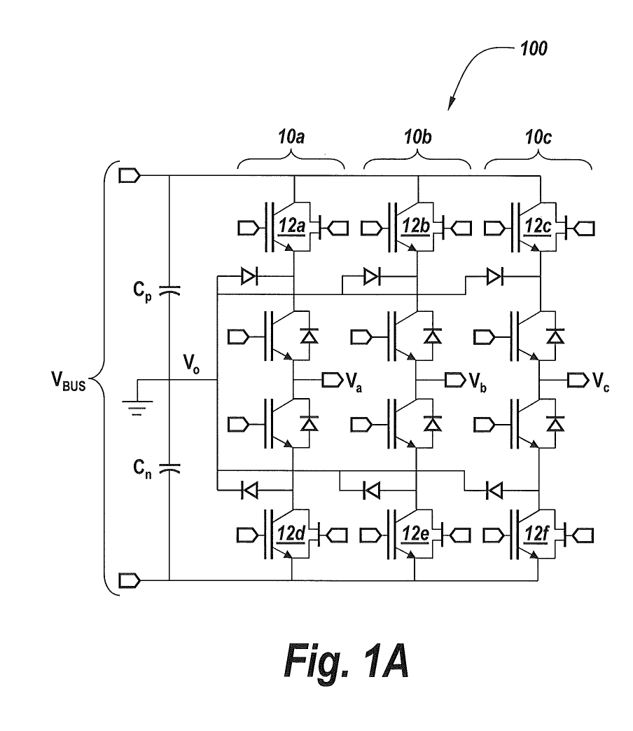

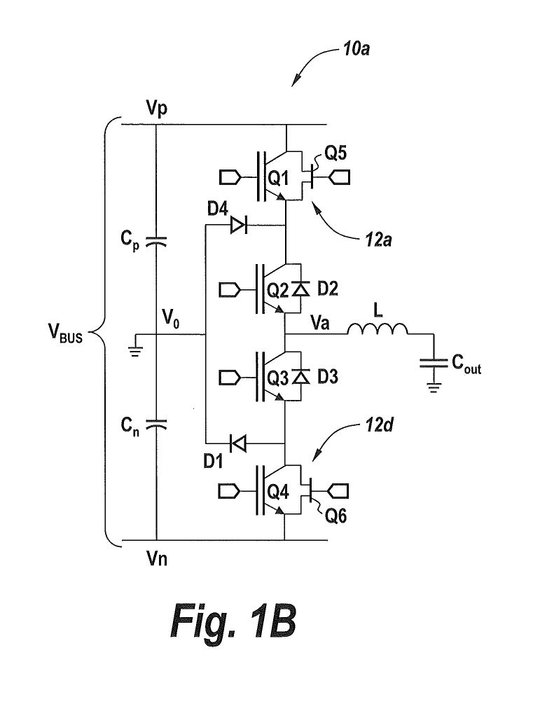

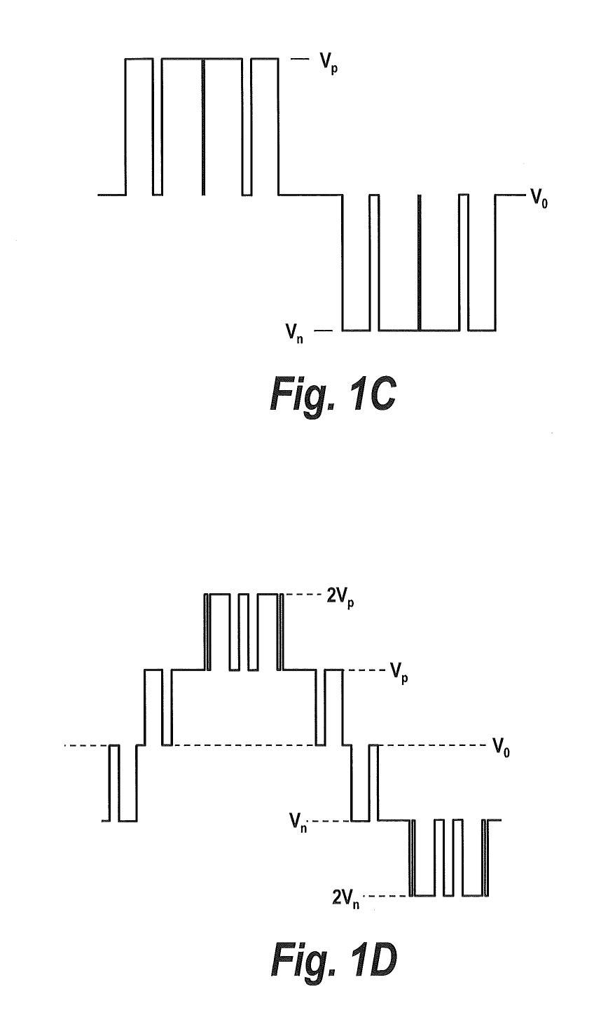

Referring now to FIGS. 1A-1B, a three level inverter 100, also referred to as a neutral-point clamped (NPC) inverter, is illustrated as including a pair of series-connected bus capacitors Cp and Cn and three equivalent inverter legs 10a, 10b and 10c, which are configured to convert a DC input voltage provided on an input bus (V_{BUS}) into three periodic leg output voltages Va, Vb and Vc. As illustrated by FIG. 1A, each inverter leg 10a, 10b and 10c includes four IGBTs connected in series in a totem pole arrangement across the input bus. The first leg 10a includes a pair of hybrid switches 12a, 12d, the second leg 10b includes a pair of hybrid switches 12b, 12e, and the third leg 10c includes a pair of hybrid switches 12c and 12f, connected as “outer” devices as illustrated. Each of the legs 10a, 10b and 10c also includes respective pairs of “inner” switching devices, which are formed as parallel combinations of IGBTs and free-wheeling diodes. According to alternative embodiments of the invention, to reduce conducting losses during light loads, the pair of inner switching devices may be configured as equivalent to the “outer” hybrid switches, by replacing the free-wheeling diodes with wide bandgap transistors.

Referring now to FIG. 1B, an embodiment of the inverter leg 10a of FIG. 1A is illustrated as including a first silicon IGBT Q1 and transistor Q5, which is configured as a wide bandgap JFET (e.g., GaN JFET). These transistors are connected in parallel as an uppermost hybrid switch 12a in the first inverter leg 10a. Similarly, a fourth silicon IGBT Q4 and transistor Q6, which is configured as a wide bandgap JFET, are connected in parallel as a lowermost hybrid switch 12d in the first inverter leg 10a. A second silicon IGBT Q2 and free-wheeling diode D2 are connected in parallel along with a third IGBT Q3 and free-wheeling diode D3. Clamp diodes D1 and D4 provide an electrical connection to a neutral point V₀ between the bus capacitors. As shown in FIG. 1B, a single-phase output voltage Va generated by the inverter leg 10a is applied to an output load, which is shown as a LC network (L and Cₒᵤₜ). This output voltage Va is generated at a node that is common to a current carrying terminal (e.g., emitter terminal) of the second silicon IGBT Q2 and a current carrying terminal (e.g., collector terminal) of the third silicon IGBT Q3, as illustrated. Switching states of the four IGBTs Q1-Q4 are illustrated by TABLE 1. As shown by this table, for one phase of operation, when IGBTs Q1 and Q2 are “on”, the output Va is pulled up to voltage Vp; when IGBTs Q2 and Q3 are “on”, the output Va is connected to V₀; and when IGBTs Q3 and Q4 are “on”, the output Va is pulled down to Vn. Moreover, from these switching states, it can be understood that IGBTs Q2 and Q3 are “on” for most of each cycle, resulting in greater conduction losses than Q1 and Q4, but with far less switching losses. In addition, the free-wheeling diodes D2 and D3 are, for most cases, soft switched as the IGBTs Q2 and Q3 are “on”, thus holding the recovery voltage across the diodes D2 and D3 to that of V_{ce} of the respective IGBTs Q2 and Q3.

TABLE 1

| IGBT | Va = Vp | Va = V₀ | Va = Vn |
|---|---|---|---|
| Q1 | On | Off | Off |
| Q2 | On | On | Off |
| Q3 | Off | On | On |
| Q4 | Off | Off | On |

FIGS. 1C-1D are graphs that illustrate the leg output voltage associated with the inverter leg of FIG. 1B and the phase-to-phase output voltage associated with the inverter of FIG. 1A, respectively. As will be understood by those skilled in the art, the effective switching frequency of the phase-to-phase voltage of FIG. 1D is twice that of the phase voltage of FIG. 1C. Accordingly, a conventional two-level inverter (not shown) is required to use twice the switching frequency of the NPC inverter of FIG. 1A in order to have the same ripple in the output load current. This fact, coupled with the intermediate voltage steps of the NPC inverter offers at least two advantages over the two-level inverter. First, there is far less switching losses in the NPC inverter and second, if an output filter (not shown) is required, the filter components can be smaller in both value and size than the filter components for a two-level inverter.

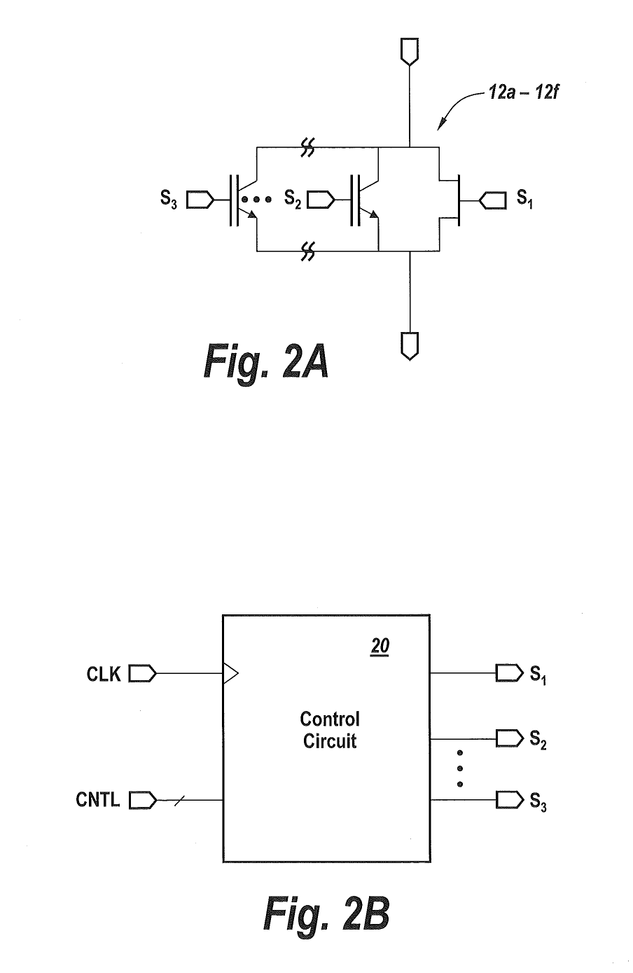

According to some embodiments of the present invention, each of the hybrid switches 12a-12f illustrated by FIGS. 1A-1B may be configured as a three-terminal wide bandgap semiconductor switching device (e.g., GaN JFET), which is responsive to a first control signal, in parallel with one or more silicon IGBTs, which are responsive to respective control signals S2, . . . , S3, as shown by FIG. 2A.

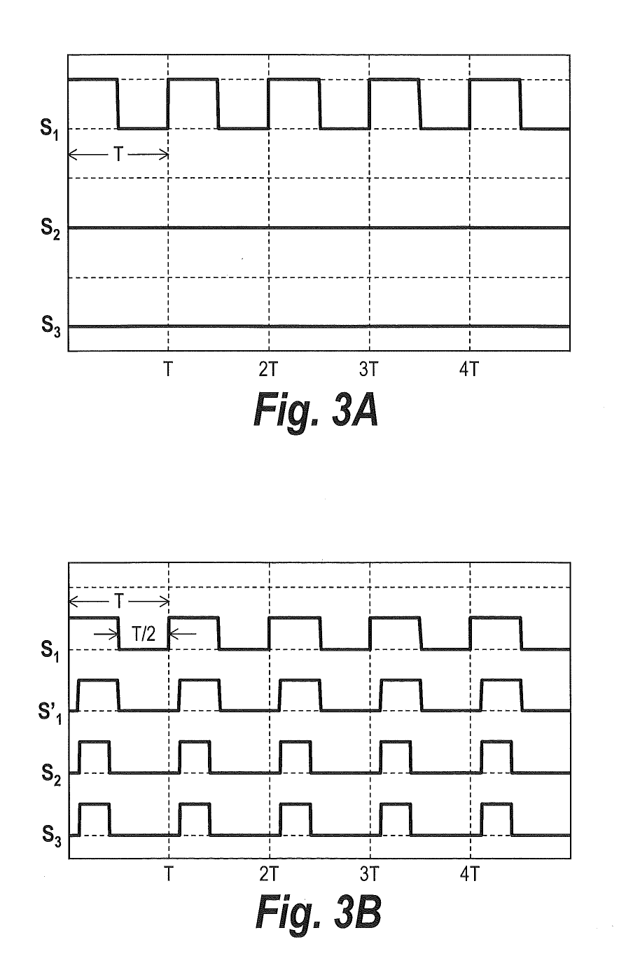

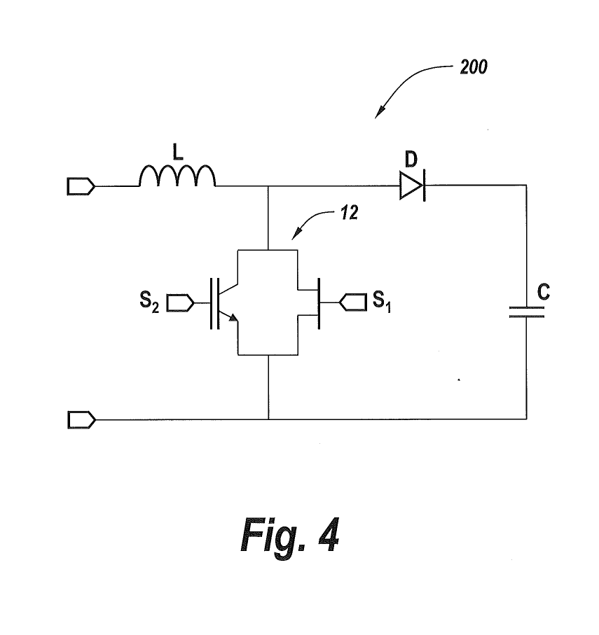

Referring now to FIG. 2B and FIGS. 3A-3B, the control signals S1-S3 may be generated as periodic signals by a control circuit 20, which is responsive to a clock signal CLK and one or more control signals CNTL. In particular, FIG. 3A is a timing diagram that illustrates the generation of a first control signal S1 having a 50% duty cycle during light or partial load conditions when the wide bandgap switching device (e.g., GaN JFET) is active and determines the overall conducting and switching losses, but the parallel IGBTs remain inactive in response to inactive control signals S2, . . . , S3. In contrast, as illustrated by FIG. 3B, during heavy load conditions, the parallel IGBTs are driven by periodic control signals having <50% duty cycles. In particular, to reduce switching losses within the hybrid switches 12a-12f, the inactive-to-active (e.g., low-to-high) transitions and active-to-inactive (e.g., high-to-low) transitions of control signals S2 and S3 occur exclusively within the active phases of the first periodic control signal S1, which means that during each active cycle, the wide bandgap switching device turns on before the IGBTs and turns off after the IGBTs. Accordingly, during heavy load conditions, conduction losses are determined by both the wide bandgap switches and IGBTs, but switching losses are determined mostly by the wide bandgap switches, which typically provide superior performance compared to Si-IGBTs in terms of on-state resistance and turn on/off losses. Alternatively, because of the typically slower turn-on characteristics of silicon IGBTs relative to GaN JFETs, the leading inactive-to-active edge of the control signal S1′ that drives the wide bandgap switching device may be aligned with the leading inactive-to-active edges of the control signals S2 and S3, in order to simplify the logic within the control circuit 20. As described hereinabove, hybrid switches according to embodiments of the invention may be utilized in all IGBT-based topologies where switching losses are significant. Thus, as illustrated by FIG. 4, an otherwise conventional boost converter 200 containing an inductor (L), diode (D) and capacitor (C) network may utilize a hybrid switch 12, which is responsive to a pair of control signals S1, S2.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A hybrid switching circuit, comprising:
first and second switching devices containing first and second unequal bandgap semiconductor materials, respectively, said first and second switching devices electrically coupled as a hybrid switch that supports parallel conduction in response to first and second control signals received at first and second control terminals of said first and second switching devices, respectively.

2. The hybrid switching circuit of claim 1, wherein the first and second switching devices are three or more terminal switching devices of different type.

3. The hybrid switching circuit of claim 2, wherein the second switching device is an insulated-gate bipolar transistor (IGBT).

4. The hybrid switching circuit of claim 3, wherein the first switching device is a three or more terminal switching device selected from a group consisting of junction field effect transistors (JFETs), insulated-gate field effect transistors (IGFETs) and high electron mobility transistors (HEMTs).

5. The hybrid switching circuit of claim 4, wherein the first switching device comprises a wide bandgap semiconductor material and the second switching device is a silicon IGBT.

6. The hybrid switching circuit of claim 5, wherein the wide bandgap semiconductor material is selected from a group consisting of silicon carbide (SiC), gallium nitride (GaN) and diamond.

7. The hybrid switching circuit of claim 2, further comprising:
a control circuit configured to drive the first and second switching devices with first and second periodic control signals having first and second unequal duty cycles, respectively.

8. The hybrid switching circuit of claim 7, wherein the first duty cycle is greater than the second duty cycle; and wherein the active phases of the second periodic control signal occur exclusively within the active phases of the first periodic control signal.

9. The hybrid switching circuit of claim 8, wherein active-to-inactive transitions of the second periodic control signal precede corresponding active-to-inactive transitions of the first periodic control signal.

10. The hybrid switching circuit of claim 9, wherein inactive-to-active transitions of the first periodic control signal precede corresponding inactive-to-active transitions of the second periodic control signal.

11. A neutral point clamped (NPC) inverter, comprising:
a bus responsive to a DC voltage;
a pair of bus capacitors electrically connected in series across said bus;
a plurality of parallel inverter legs electrically connected across said bus, said plurality of parallel inverter legs comprising a first totem pole arrangement of four silicon IGBTs electrically connected in series and first and second wide bandgap transistors electrically connected in parallel with first and fourth IGBTs in the first totem pole arrangement;
a first clamp diode electrically connected between a common node in said pair of bus capacitors and a first node in the first totem pole arrangement shared by the first and second IGBTs; and
a second clamp diode electrically connected between the common node in said pair of bus capacitors and a second node in the first totem pole arrangement shared by the third and fourth IGBTs.

12. The NPC inverter of claim 11, wherein the first totem pole arrangement further comprises first and second free-wheeling diodes electrically coupled across second and third IGBTs therein.

13. The NPC inverter of claim 11, further comprising a control circuit configured to drive the first wide bandgap transistor and the first IGBT with first and second periodic control signals having unequal duty cycles when the first totem pole arrangement is driving a first load connected thereto with a first load current.

14. The NPC inverter of claim 13, wherein the control circuit is further configured to drive the second wide bandgap transistor and the fourth IGBT with third and fourth periodic control signals having unequal duty cycles.

15. The NPC inverter of claim 13, wherein the first duty cycle is greater than the second duty cycle; and wherein the active phases of the second periodic control signal occur exclusively within the active phases of the first periodic control signal.

16. The NPC inverter of claim 13, wherein the first duty cycle is greater than the second duty cycle; wherein active-to-inactive transitions of the second periodic control signal precede corresponding active-to-inactive transitions of the first periodic control signal.

17. The NPC inverter of claim 16, wherein inactive-to-active transitions of the first periodic control signal precede corresponding inactive-to-active transitions of the second periodic control signal.

18. A hybrid switching circuit, comprising:
first and second switching transistors of different type electrically connected in parallel; and
a control circuit configured to drive the first and second switching transistors with first and second periodic control signals having first and second unequal duty cycles, respectively, said second periodic control signal having active phases exclusively within the active phases of the first periodic control signal.

19. The hybrid switching circuit of claim 18, wherein the second switching transistor is an insulated-gate bipolar transistor (IGBT); and wherein the first switching device is a three or more terminal switching device selected from a group consisting of junction field effect transistors (JFETs), insulated-gate field effect transistors (IGFETs) and high electron mobility transistors (HEMTs).

20. The hybrid switching circuit of claim 19, wherein the first switching device comprises a wide bandgap semiconductor material and the second switching device is a silicon IGBT; and wherein the wide bandgap semiconductor material is selected from a group consisting of silicon carbide (SiC), gallium nitride (GaN) and diamond.
